(19) United States
(12) Patent Application Publication
(10) Pub. No.: US 2009/0250731 A1
(43) Pub. Date: Oct. 8, 2009

(54) Field-effect transistor structure and fabrication method thereof

(76) Inventors: Tsung-Yeh Yang, Hsinchu City (TW); Tri-Rung Yew, Hsinchu City (TW)

Correspondence Address: J.C. Patents, Suite 250, 4 Venture, Irvine, CA, 92618, US

(21) Appl. No.: 12/080,505

(22) Filed: Apr. 2, 2008

(51) Int. Cl. H01L 29/00; H01L 21/3205

(52) U.S. Cl. 257/288; 438/587; 257/E29.001; 257/E21.294

(57) ABSTRACT

A field-effect transistor (FET) structure is provided. The FET structure includes a gate substrate, a dielectric layer, conductive electrodes, and a carbon nanotube (CNT). The gate substrate is made of a conductive material. The dielectric layer is disposed on the substrate. The conductive electrodes are disposed on the dielectric layer, and contain nickel and chromium. The CNT is disposed on the dielectric layer and electrically connects two conductive electrodes

### BACKGROUND OF THE INVENTION

1. Field of the Invention

The present invention generally relates to an integrated circuit structure and a fabrication method thereof, in particular, to an FET structure and a fabrication method thereof.

2. Description of Related Art

In highly integrated semiconductor devices, generally a doped silicon material is adopted to form sources, drains, and gates of FETs. In order to increase the density of the devices, the distances between the sources and the drains must be reduced.

FIG. 1A is a schematic cross-sectional view of a conventional commonly used metal oxide semiconductor FET (MOSFET) structure. Referring to FIG. 1A, the FET structure 10a includes a substrate 100, a dielectric layer 102, a source and drain 104, and a gate 106. The source and drain 104 is disposed in the substrate 100, the dielectric layer 102 is disposed on the substrate 100, and the gate 106 is disposed on the dielectric layer 102.

In order to reduce the size and increase the density of a device, generally the distance between the source and drain 104 is reduced, and meanwhile the thickness of the dielectric layer 102 is reduced. However, the decrease of the thickness of the dielectric layer 102 may result in an increase of the leakage current of the device. In order to solve this problem, a carbon nanotube filed-effect transistors (CNTFET) is used to replace the conventional MOSFET. As for another conventional CNTFET, the structure of the CNTFET includes a substrate, a dielectric layer, metal electrodes, and a CNT. The dielectric layer is disposed on the substrate. The metal electrodes are disposed on the dielectric layer. The CNT is disposed on the dielectric layer, and between the metal electrodes. Since the field-effect characteristics of the CNTFET structure will not be severely impacted by the thickness of the dielectric layer, the problem of the leakage current in the FET can be solved by increasing the thickness of the dielectric layer. Further, the CNTFET structure has a simpler fabrication process than that of the MOSFET structure, and the cost thereof is lower.

However, in the aforementioned CNTFET structure, the CNT is deposited on a whole chip, and may exhibit both metallic and semiconducting characteristics. If the CNT exhibits the metallic characteristic, the device will lose the field-effect characteristic and is impossible to form an FET.

### SUMMARY OF THE INVENTION

Accordingly, the present invention is directed to a CNTFET structure, having improved uniformity of the CNT, such that all the devices in a chip can form a CNTFET.

The present invention provides a transistor structure, which includes a substrate, a dielectric layer, two metal electrodes, and a CNT. The dielectric layer is disposed on the gate substrate. The two metal electrodes are disposed oh the dielectric layer, and contain nickel and chromium. The CNT is disposed on the dielectric layer, and connected between the two metal electrodes.

In a method of fabricating an FET structure according to an embodiment of the present invention, the substrate is made of a doped silicon material.

In a method of fabricating an FET structure according to an embodiment of the present invention, the substrate made of a doped silicon material serves as a gate of the FET.

In a method of fabricating an FET structure according to an embodiment of the present invention, the dielectric layer is made of, for example, silicon dioxide or a well-known high dielectric material selected from among zirconium oxide, tantalum dioxide, hafnium oxide, and hafnium silicates.

In a method of fabricating an FET structure according to an embodiment of the present invention, the dielectric layer is made of, for example, silicon dioxide, and the thickness of the silicon dioxide is in a range of 10 to 500 nm.

In a method of fabricating an FET structure according to an embodiment of the present invention, the metal electrodes are made of, for example, a nickel-based alloy.

In a method of fabricating an FET structure according to an embodiment of the present invention, the metal electrodes are made of, for example, a nickel-chromium alloy or a derivative thereof.

In a method of fabricating an FET structure according to an embodiment of the present invention, the metal electrodes are made of, for example, a nickel-chromium alloy, and a proportion of nickel in the nickel-chromium alloy is in a range of 1-20%.

In a method of fabricating an FET structure according to an embodiment of the present invention, the metal electrodes are made of, for example, a nickel-chromium alloy, and serve as a source and drain of the FET.

In a method of fabricating an FET structure according to an embodiment of the present invention, a forming method of the CNT is, for example, a chemical vapor deposition (CVD) process.

In a method of fabricating an FET structure according to an embodiment of the present invention, the CNT is formed at a temperature of 800 to 900° C., and at a pressure of 1 to 10 torr. An introduced carbonaceous gas is, for example, selected from among C₂H₂, CH₄, C₂H₅OH, and C₆H₆, and a carrier gas is, for example, selected from among H₂ and Ar.

In a method of fabricating an FET structure according to an embodiment of the present invention, a flow rate ratio of C₂H₂ to H₂ is in a range of, for example, 0.1 to 10.

An FET SEM fabricated according to an embodiment of the present invention and the field-effect characteristics thereof are shown in FIGS. 3 and 4. In the process of fabricating the FET structure of the present invention, the CNT is directly formed on metal electrodes containing nickel for forming the CNT, and thus the step of additionally forming a catalyst layer of the CNT is saved, thereby simplifying the fabrication process. Also, the purpose of mass production can be achieved by first defining the position of the source and drain of the FET through a patterning process and then forming the CNT through a CVD process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a conventional MOSFET structure.

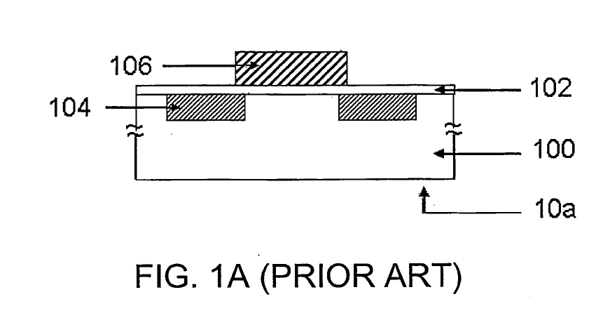

FIGS. 2A and 2B are cross-sectional views showing processes of fabricating a CNTFET structure according to an embodiment of the present invention.

FIG. 3 is SEM photograph of a CNTFET structure according to an embodiment of the present invention.

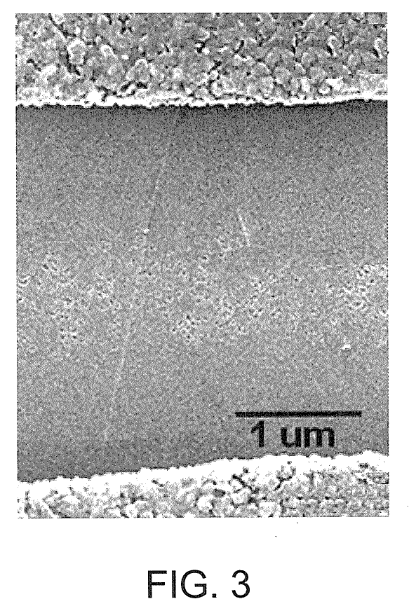

FIG. 4 shows field-effect characteristics of a CNTFET structure according to an embodiment of the present invention.

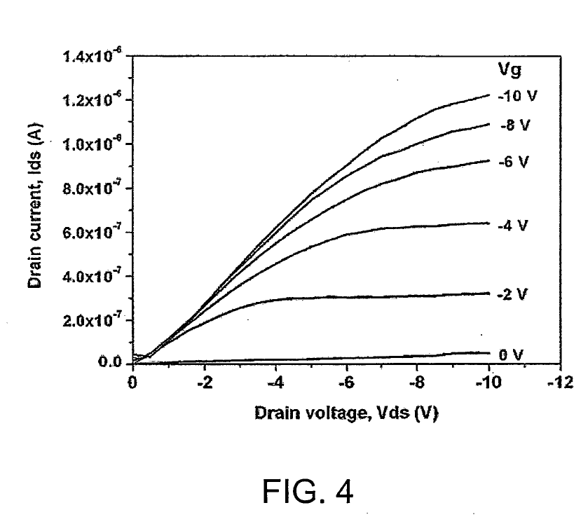

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

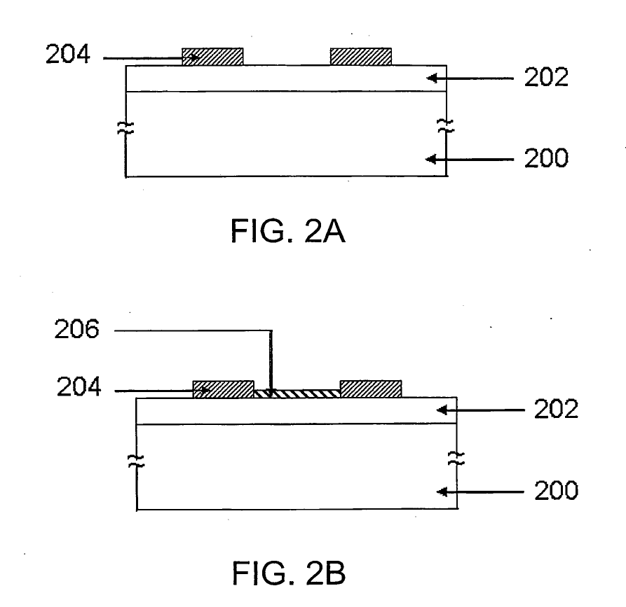

FIGS. 2A and 2B are cross-sectional views showing processes of fabricating an FET structure according to an embodiment of the present invention. Referring to FIG. 2A, first, a gate substrate 200 is provided. The gate substrate 200 is made of a doped silicon material. The silicon material is doped to enhance the electrical conductivity of the gate substrate 200. Next, a dielectric layer 202 is formed on the gate substrate 200. The dielectric layer 202 is made of, for example, silicon dioxide, and the thickness of the silicon dioxide is in a range of 10 to 500 nm. After that, metal electrodes 204 are formed on the dielectric layer 202. The metal electrodes 204 are made of, for example, a nickel-chromium alloy which is formed by the following method. For example, a nickel-chromium thin film is deposited on the dielectric layer 202. Next, the metal electrode pattern is defined through photolithography and etching, and then the nickel-chromium alloy is formed at a high temperature of, for example, 800 to 900° C. When the metal electrodes 204 are made of a nickel-chromium alloy, the original thickness of a nickel thin film is in a range of 1 to 10 nm, and a proportion of nickel in the nickel-chromium alloy is in a range of 1-20%. In an embodiment, the proportion of nickel in a nickel-chromium alloy is in a range of, for example, 10-20%.

Next, referring to FIG. 2A, the metal electrodes 204 are formed on the dielectric layer 202. The metal electrodes 204 are made of, for example, a nickel-chromium alloy. Further, the metal electrodes 204 may serve as a source and drain of an FET, and also a catalyst for forming the CNT in the subsequent process.

Since the CNT must be formed by the use of the catalyst, the CNT may be formed just between defined metal electrodes, and will not be formed in a region without metal electrodes on the chip. Therefore, the self-alignment process for forming the FET can be extensively applied to devices in different directions.

Then, referring to FIG. 2B, a CNT 206 is formed on the dielectric layer 202, and electrically connected between the two metal electrodes 204. The CNT 206 is formed by, for example, a CVD process at a temperature of, for example, 800 to 900° C., and at a pressure of, for example, 1 to 10 torr. An introduced gas is, for example, selected from among C₂H₂, H₂, and Ar. The flow rate of C₂H₂ is in a range of, for example, 1 to 10 sccm. The flow rate ratio of C₂H₂ to H₂ is in a range of, for example, 0.1 to 10. In an embodiment, the temperature is, for example, 900° C., the pressure is, for example, 3 torr, and the flow rate ratio of C₂H₂ to H₂ is, for example, 1:4.

In this embodiment, the CNT 206 is directly formed between the metal electrodes 204 containing nickel for forming the CNT 206, and meanwhile the two metal electrodes 204 connected by the CNT 206 serve as a source and drain of the FET. The metal electrodes 204 are, for example, made of a nickel-chromium alloy and serve as a catalyst for forming the CNT 206, which is more effective than nickel used as a catalyst for forming the CNT 206, thereby effectively enhancing the uniformity of the CNT. Moreover, the FET formed by the CNT 206 exhibits the field-effect characteristics.

In view of the above, in the FET structure provided by the present invention, the CNT is directly formed between two metal electrodes containing nickel. The CNT formed by metal electrodes made of a nickel-chromium alloy has a higher uniformity, and the device formed by the CNT exhibits the field-effect characteristics. Moreover, through the present invention, a self-aligned FET can be formed, and thus the fabrication process is simplified, and the purpose of mass production can be achieved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A field-effect transistor (FET) structure, comprising:
a gate substrate, made of a silicon material;
a dielectric layer, disposed on the gate substrate;
two metal electrodes, disposed on the dielectric layer; and
a carbon nanotube (CNT), disposed on the dielectric layer, wherein the carbon nanotube is self-aligned the two metal electrodes so that the carbon nanotube is electrically connected between the two metal electrodes.

2. (canceled)

3. The FET structure according to claim 1, wherein the dielectric layer is made of silicon dioxide or a well-known high dielectric material selected from among zirconium oxide, tantalum dioxide, hafnium oxide, and hafnium silicates, and a thickness of the dielectric layer is in a range of 10 to 500 nm.

4. The FET structure according to claim 1, wherein the metal electrodes are made of a nickel-chromium alloy, or a derivative thereof.

5-15. (canceled)

16. A field-effect transistor (FET) structure, comprising:
a silicon gate substrate;
a dielectric layer disposed on the silicon gate substrate;
two metal electrodes disposed on the dielectric layer; and
a carbon nanotube (CNT) self-assembled with the two metal electrode on the dielectric layer as the two metal electrode serve as a formation catalyst of the carbon nanotube.

17. The FET structure according to claim 16, wherein the dielectric layer is made of silicon dioxide or a well-known high dielectric material selected from among zirconium oxide, tantalum dioxide, hafnium oxide, and hafnium silicates, and a thickness of the dielectric layer is in a range of 10 to 500 nm.

18. The FET structure according to claim 16, wherein the metal electrodes are made of a nickel-chromium alloy, or a derivative thereof.
